(19) United States
(12) Patent Application Publication
(10) Pub. No.: US 2024/0249035 A1
(43) Pub. Date: Jul. 25, 2024

(54) LIGHTING DESIGN OF NEW OUTDOOR SITE

(71) Applicant: SIGNIFY HOLDING B.V., Eindhoven (NL)

(72) Inventors: NAM CHIN CHO, PEACHTREE CITY, GA (US); KAITLIN BURKE, ATLANTA, GA (US); ROBERT BABIARZ, MISSISSAUGA (CA)

(21) Appl. No.: 18/100,884

(22) Filed: Jan. 24, 2023

(51) Int. Cl. G06F 30/13; G06T 3/40; G06T 3/60; G06T 11/00

(52) U.S. Cl. CPC G06F 30/13; G06T 3/40; G06T 3/60; G06T 11/00; G06F 3/0482; G06T 2200/24

(57) ABSTRACT

A lighting design method for outdoor areas based on light fixture model augmentation includes displaying a satellite view image of an area on a display screen. The method further includes displaying a site plan image on the display screen, where the site plan image is displayed overlaid on the satellite view image that is displayed on the display screen. The method also includes displaying a light fixture model, where the light fixture model is augmented onto the site plan image displayed on the display screen. The method further includes generating illuminance information based on at least one or more parameters associated with a light fixture represented by the light fixture model and displaying the illuminance information on the display screen, where the illuminance information is displayed overlaid on the site plan image.

### TECHNICAL FIELD

The present disclosure relates generally to lighting designs, and more particularly to lighting design of a new outdoor site based on augmented satellite view image.

### BACKGROUND

Some lighting design methods for outdoor spaces may require examining an outdoor area including structures in the outdoor area, etc. and estimating lighting requirements for the outdoor area. The lighting requirement estimation is often performed using modelling tools that rely on a 3-dimensional (3D) model of the outdoor area. However, the generation of a 3D model of an outdoor space can be complex and cumbersome. Some other lighting design methods for outdoor spaces may involve the use of site plan drawings. However, such lighting design methods often require a manual process of correlating a site plan with an existing imagery of an outdoor area. The manual process of correlating a site plan with an existing imagery of an outdoor area can be time consuming and cumbersome. Thus, a solution that enables performing a more efficient lighting design for outdoor spaces is desirable.

### SUMMARY

In general, the present disclosure relates generally to lighting designs, and more particularly to lighting design of a new outdoor site, such as a new construction site, based on augmented satellite view image. In an example embodiment, a lighting design method for outdoor areas based on light fixture model augmentation includes displaying a satellite view image of an area on a display screen. The method further includes displaying a site plan image on the display screen, where the site plan image is displayed overlaid on the satellite view image that is displayed on the display screen. The method also includes displaying a light fixture model, where the light fixture model is augmented onto the site plan image displayed on the display screen. The method further includes generating illuminance information based on at least one or more parameters associated with a light fixture represented by the light fixture model and displaying the illuminance information on the display screen, where the illuminance information is displayed overlaid on the site plan image.

In another example embodiment, a device for performing a lighting design for outdoor areas based on light fixture model augmentation includes a user interface configured to receive user inputs, a display screen, and a processor. The processor is configured to display a satellite view image of an area on the display screen and display a site plan image on the display screen in response to a user input received via the user interface, where the site plan image is displayed overlaid on the satellite view image displayed on the display screen. The processor is further configured to display a light fixture model on the display screen, where the light fixture model is augmented onto the site plan image displayed on the display screen. The processor is also configured to generate illuminance information based on at least one or more parameters associated with a light fixture represented by the light fixture model and display the illuminance information on the display screen, wherein the illuminance information is displayed overlaid on the site plan image.

These and other aspects, objects, features, and embodiments will be apparent from the following description and the claims.

### BRIEF DESCRIPTION OF THE FIGURES

Reference will now be made to the accompanying drawings, which are not necessarily drawn to scale, and wherein:

FIG. 1 illustrates a system for performing lighting design based on an existing satellite view image from a mapping service according to an example embodiment;

FIG. 2 illustrates a satellite view image of an outdoor area displayed on a user device of FIG. 1 according to an example embodiment;

FIG. 3 illustrates a user input window for selecting a site plan image for overlaying onto the satellite view image of the outdoor area displayed on the user device as shown in FIG. 1 according to an example embodiment;

FIG. 4 illustrates a site plan image overlaid onto the satellite view image of the outdoor area displayed on the user device as shown in FIG. 1 according to an example embodiment;

FIG. 5 illustrates a rotation guide for rotating the site plan image displayed on a user device of FIG. 1 according to an example embodiment;

FIG. 6 illustrates a light fixture menu displayed on a user device of FIG. 1 according to an example embodiment;

FIG. 7 illustrates a light fixture model of a light fixture augmented onto the satellite view image shown in FIG. 5 according to an example embodiment;

FIG. 8 illustrates the light fixture model of the light fixture of FIG. 6 augmented onto site plan image shown in FIG. 7 according to an example embodiment;

FIG. 9 illustrates multiple light fixture models augmented on the site plan image shown in FIG. 7 according to an example embodiment;

FIG. 10 illustrates the light fixture models augmented on the site plan image shown in FIG. 7 according to an example embodiment;

FIG. 11 illustrates illuminance information overlaid on the site plan image according to an example embodiment; and

FIG. 12 illustrates an outdoor lighting design method for an outdoor area based on light fixture model augmentation according to an example embodiment.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different drawings may designate like or corresponding but not necessarily identical elements.

### DETAILED DESCRIPTION OF THE EXAMPLE EMBODIMENTS

In the following paragraphs, example embodiments will be described in further detail with reference to the figures. In the description, well-known components, methods, and/or processing techniques are omitted or briefly described. Furthermore, reference to various feature(s) of the embodiments is not to suggest that all embodiments must include the referenced feature(s).

In some example embodiments, a lighting professional or a customer may use a user device to execute one or more software applications to create and visualize lighting solutions for new construction site plans. A user may use the user device to import an existing satellite view image of an outdoor area, display the satellite view image, import a site plan image, display the site plan image overlaid on the satellite view image, augment the site plan image and the satellite view image with one or more light fixture models, and calculate and display illumination information, such as illuminance values or other illuminance indicators, overlaid on the site plan view. The user device may execute operations based on user inputs provided to the user device. The lighting design method using the user device can save time and effort in sales, design, and approval processes of light designs.

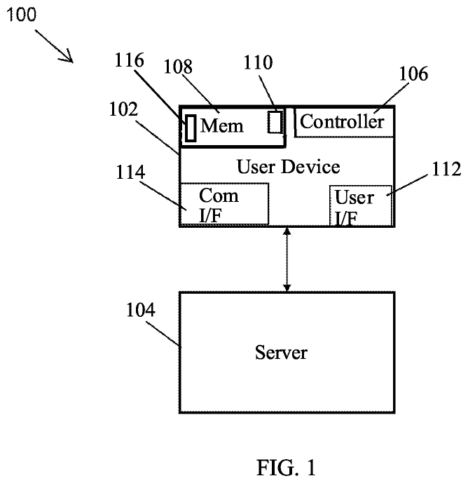

Now turning to the drawings, FIG. 1 illustrates a system 100 for performing lighting design based on an existing satellite view image from a mapping service according to an example embodiment. In some example embodiments, the system 100 may include a user device 102 (i.e., a lighting design device) and a server 104. The user device 102 may be communicably coupled to the server 104 via connections that include wired and/or wireless connections. The server 104 may include or may communicate with a map server (e.g., a Google Maps server) that provides satellite view images to the user device 102 for performing lighting design.

In some example embodiments, the user device 102 may include a controller/processor 106 (e.g., one or more microprocessors or microcontrollers and support components), a memory device 108 (e.g., one or more static memory device), a user interface 112, and a communication interface 114. An executable software code 110 may be stored in the memory device 108. Other information including site plan images, light fixture models, parameters associated with the light fixtures and/or light fixture models, photometric data, etc. may also be stored in the memory device 108. The controller 106 may execute the software code 110 and/or other software code to perform operations described herein with respect to the user device 102. In general, the controller 106 may execute the software code 110 and/or other software code that may include augmented reality and/or mixed reality software code to perform operations described herein with respect to the user device 102. In some alternative embodiments, information and data may be stored in and/or accessed from the server 104 instead of from the memory device 108 without departing from the scope of this disclosure.

In some example embodiments, data 116 stored in the memory device 108 may include information such as site plan images, light fixture models, etc. The data 116 may also include information, such as photometric data associated with light fixture models, that can be used to calculate illuminance as can be readily understood by those of ordinary skill in the art with the benefit of this disclosure. For example, the lighting design models stored in the memory device 108 may each be associated with parameters such as photometric data, mounting height, vertical tilt, etc. corresponding to the light fixtures represented by the lighting design models.

In some example embodiments, the user interface 112 may include one or more of a touch-sensitive screen, a keyboard, a mouse, a display screen, and/or another user interface component for receiving user inputs by the user device 102, for displaying information, etc. For example, the user device 102 may be a desktop, a laptop, a tablet, a smartphone, or another type of user device. The user device 102 may communicate with the server 104 and other devices via the communication interface 114 that may include wired and/or wireless communication components as can be readily understood by those of ordinary skill in the art with the benefit of this disclosure.

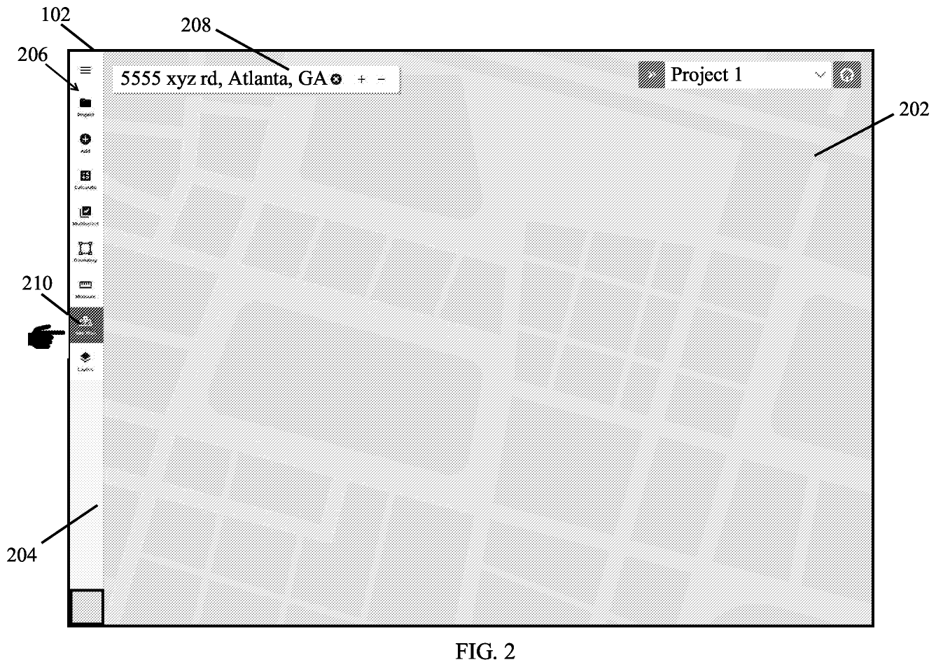

In some example embodiments, a user may operate the user device 102 to display a satellite view image of an area on the user device 102. For example, the user may provide a location (e.g., address) of an area to the user device 102 via the using interface 112, and, in response, the user device 102 may obtain the satellite view image of the area from the server 104 and may display the satellite view image, for example, on the display screen of the user device 102 as shown in FIG. 2. The satellite view image may be an online or offline interactive image as readily understood by those of ordinary skill in the art with the benefit of this disclosure.

FIG. 2 illustrates a satellite view image 202 of an outdoor area displayed on the user device 102 of FIG. 1 according to an example embodiment. Referring to FIGS. 1 and 2, in some example embodiments, the user device 102 may display the satellite view image 202 on a display screen 204 of the user interface 112 of the user device 102 shown in FIG. 1. For example, a user may provide an address to the user device 102 as a user input, and the user device 102 may display the satellite view image 202 on the display screen 204 of the user device 102 in response to the user input. For example, the user may enter (e.g., type) an address in an address field 208 displayed on the user device 102. In response, the user device 102 may obtain the satellite view image 202 that includes the area corresponding to the address. For example, the satellite view image 202 may show an area that includes the specific address location. The boundary of the entire area shown the satellite view image 202 may be limited to a particular (e.g., default) distance from the exact location of the address provided by the user in the address field 208.

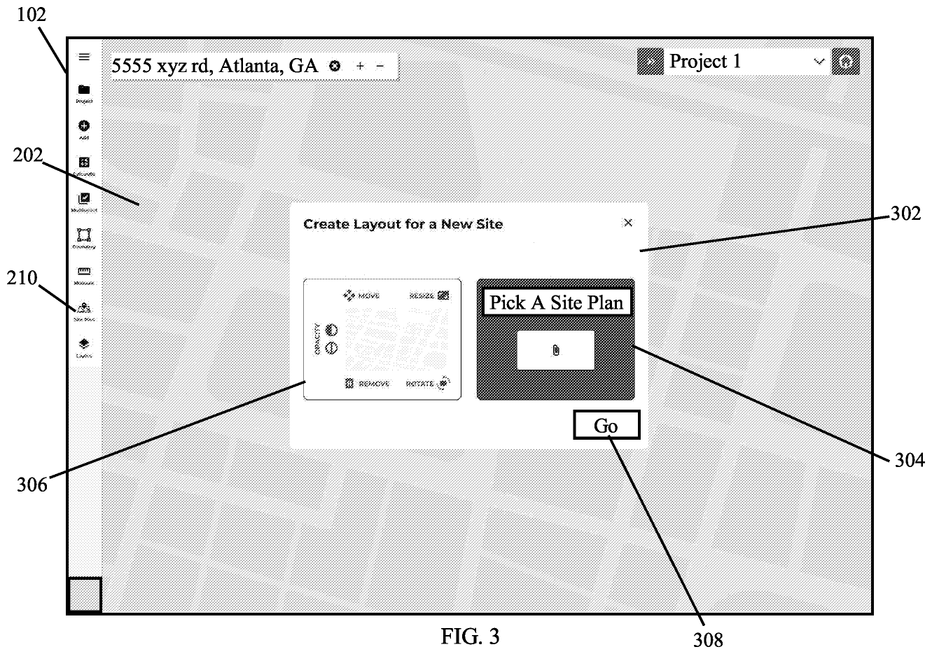

In some example embodiments, the user device 102 may display a menu 206 of user input icons including a site plan user input icon 210 that may be selected to initiate the uploading and displaying of a site plan image overlaid on the satellite view image 202. For example, a user may select the site plan user input icon 210 using a finger or a cursor that is controlled by a mouse. FIG. 3 illustrates a user input window 302 for selecting a site plan image for overlaying onto the satellite view image 202 of the outdoor area displayed on the user device 102 as shown in FIG. 2 according to an example embodiment. Referring to FIGS. 1-3, in some example embodiments, the user device 102 may display the user input window 302 in response to the user selecting the site plan user input icon 210. To illustrate, the user input window 302 may include an upload section 304 that is selectable by the user to location a site plan image for uploading. For example, a user may touch or click on the upload section 304, which may result in a file explorer window that can be used to locate a file that includes a desired site plan image. The user input window 302 may also include a guide section 306 that illustrates operations that can be performed to manipulate an uploaded and displayed site plan image. After the site plan image is uploaded, the user may provide an input to the user device 102 to proceed with uploading and displaying the selected site plan image. For example, the user may touch or click on the Go icon 308.

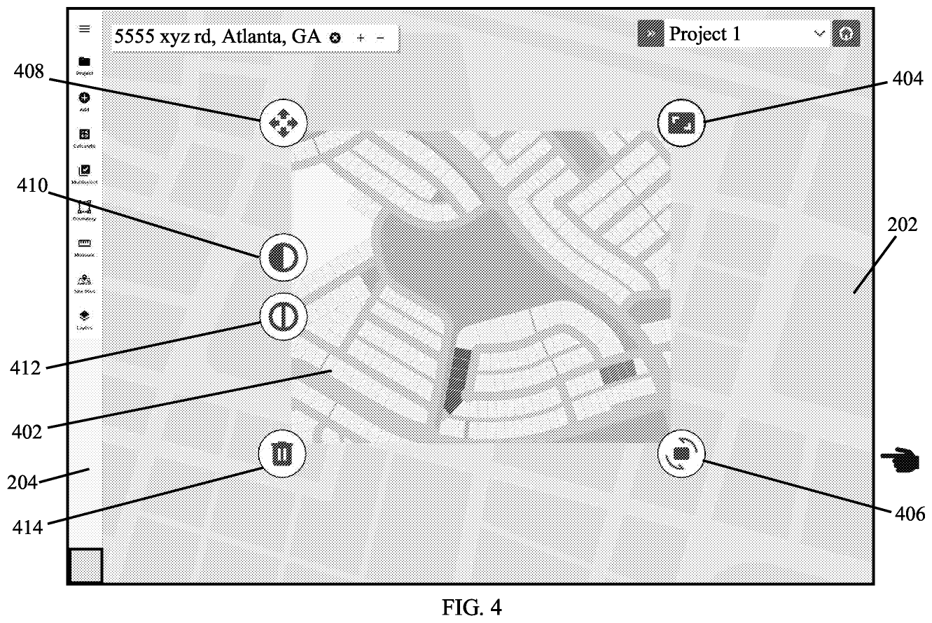

FIG. 4 illustrates a site plan image 402 overlaid onto the satellite view image 202 of the outdoor area displayed on the user device 102 as shown in FIG. 2 according to an example embodiment. Referring to FIGS. 1-4, in some example embodiments, the user device 102 may display the site plan image 402 overlaid onto the satellite view image 202 in response to the use providing one or more inputs to the user device 102 as described above. For example, the site plan shown in the site plan image 402 may be a construction site plan.

In some example embodiments, upon the uploading of the site plan image 402, the user device 102 may automatically place, rotate, and/or resize the site plan image 402 with respect to the satellite view image 202. To illustrate, the site plan image 402 may include information that indicates orientation (e.g., indication of north) and default actual perimeter dimensions. Because the satellite view image 202 includes orientation information and location information that enable the user device 102 to determine actual distances in the area shown in the satellite view image 202, the user device 102 can automatically rotate and resize the site plan image 402 with respect to the satellite view image 202. The user device 102 may also automatically move, rotate, and resize the site plan image 402 with respect to the satellite view image 202 based on structural features such as surrounding roadways, parking spaces, buildings, etc. in the area as shown in the satellite view image 202. For example, the satellite view image 202 may indicate specific features such as roadways, parking spaces, buildings, etc., and the user device 102 may identify these features from satellite view image 202. The user device 102 may automatically move, rotate, and/or resize the site plan image 402 based on the locations of these features, for example, to avoid overlapping existing structures (e.g., buildings), for proximity to existing structures (e.g., parking spaces and roadways), etc.

In some example embodiments, a user may resize, rotate, move, delete the site plan image 402 using the user device 102 by provide inputs to the user device 102. In general, the user may use the user device 102 to change the location, the size, and the orientation of the site plan image 402 such that the site plan image 402 is at a desired location and has the desired size and orientation with respect to the satellite view image 202.

In some example embodiments, the user may select a resize user input icon 404 to enable the resizing of the site plan image 402. To illustrate, after touching or clicking on the resize user input icon 404, the user may use a cursor or a finger at a desired perimeter or edge of the site plan image 402 to increase or reduce the size of the site plan image 402. The user may also use the user device 102 to move the site plan image 402 relative to the satellite view image 202 by selecting the move icon 408 and clicking down or touch the site plan image 402 while moving to the desired location.

In some example embodiments, the user may use the user device 102 to increase the transparency (i.e., reduce opacity) of the site plan image 402 by clicking on or touching the transparency icon 412. Making the site plan image 402 less opaque may enable the user to more easily determine whether the site plan shown in the site plan image 402 is suited for the outdoor area shown in the satellite view image 202. By making the site plan image 402 less opaque, the user may determine whether a structure in the site plan image 402 can be located at a particular location in the outdoor area shown in the satellite view image 202. For example, the user may move and/or rotate the site plan image 402 in response to determining that an existing structure in the outdoor area would interfere with a structure in the site plan image 402. The user may also use the user device 102 to reduce the transparency (i.e., increase opacity) of the site plan image 402 by clicking on or touching the opacity icon 410.

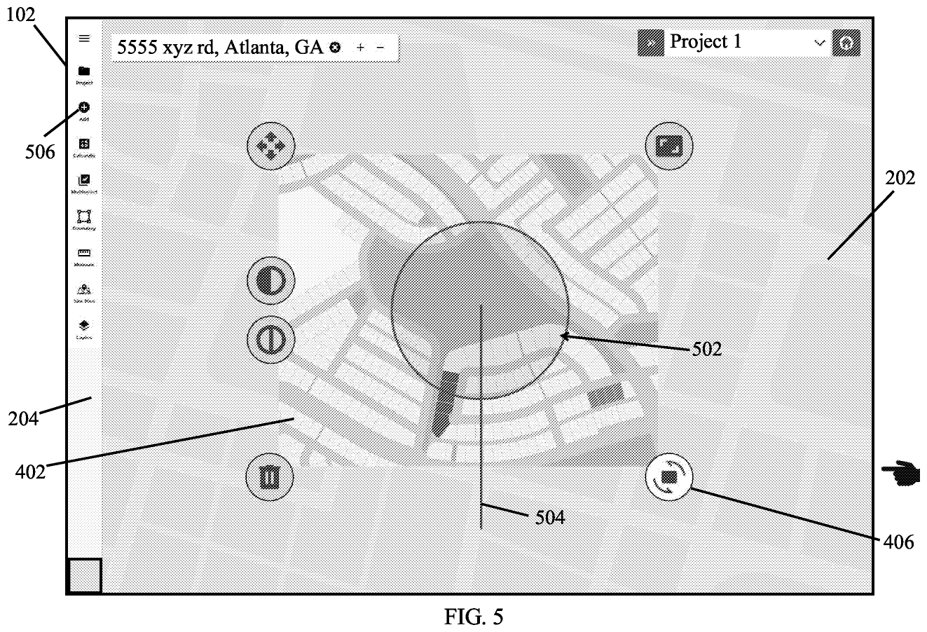

In some example embodiments, the user may select a rotate user input icon 406 to rotate the site plan image 402 relative to the satellite view image 202. For example, the user may provide an input to the user device 102 by clicking on or touching with a finger the rotate user input icon 406. In response, the user device 102 may display a rotation guide 502 shown in FIG. 5. FIG. 5 illustrates the rotation guide 502 for rotating the site plan image 402 displayed on a user device of FIG. 1 according to an example embodiment. For example, the rotation guide 502 may include a handle 504 that may be selected by a user using a finger or a cursor to rotate the site plan image 402 relative to the satellite view image 202. The user may click on or touch the rotate user input icon 406 to remove the rotation guide 502 from the display screen 204.

In some example embodiments, a user may use the user device 102 to augment the satellite view image 202 and the site plan image 402 with light fixture models. For example, the user may provide an input to the user device 102 by clicking on or touching an add light fixture user input icon 506. In response, the user device 102 may display a light fixture menu from which the user can select.

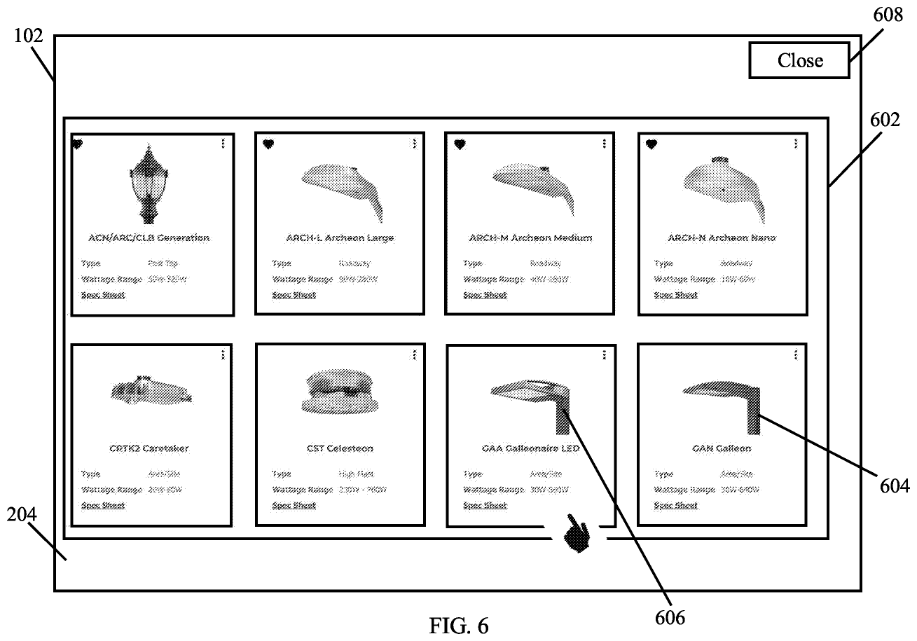

FIG. 6 illustrates a light fixture menu 602 displayed on the user device 102 according to an example embodiment. In some example embodiments, the user device 102 may display on the display screen 204 of the user device 102 the light fixture menu 602 in response to a user providing an input to the user device 102, for example, by clicking on or touching the add light fixture user input icon 506 shown in FIG. 5. The light fixture menu 602 may show images of light fixtures along with names and some parameters associated with the light fixtures. For example, the light fixture menu 602 may show light fixtures 604, 606 and related information such as the names of the light fixtures.

In some example embodiments, a user may provide an input to the user device 102 to select a light fixture from the light fixture menu 602, for example, by clicking on or touching the image or near the image of the light fixture. For example, a user may select the light fixture 606 by touching the image of the light fixture 606 shown in the menu 602 of the light fixtures. The user may close the light fixture menu 602 by clicking on the close icon 608, for example, after selecting a light fixture. In response to the selection of a light fixture from the light fixture menu 602, the user device may display a light fixture model of the selected light fixture augmented on the satellite view image 202 shown in FIG. 5.

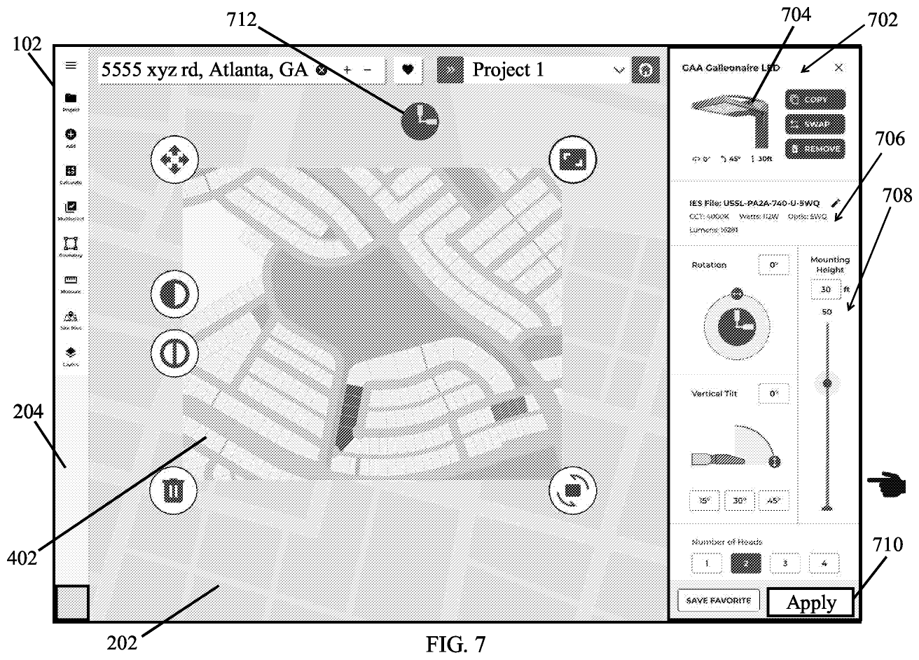

FIG. 7 illustrates a light fixture model 712 of the light fixture 606 augmented on the satellite view image 202 shown in FIG. 5 according to an example embodiment. Referring to FIGS. 5-7, in some example embodiments, the user device 102 may display the light fixture model 712 at a default location upon the selection of the light fixture 606 from the light fixture menu 602. The user device 102 may also display on the display screen 204 light fixture information 702 related to the light fixture 606. For example, the light fixture information 702 may include an image 704 of the light fixture 606, photometric data 706, and user adjustable parameters 708.

For example, the user configurable parameters 708 may including the mounting height of the light fixture 606, vertical tilt angle, orientation (e.g., the angle of the light fixture head in a horizontal plane), and the number of heads that light fixture 606 includes. The photometric data 706 may also be changeable by selecting a different photometric data file (e.g., an IES file) that is stored in the user device 102 or obtained from a server, such as the server 104 shown in FIG. 1. For example, the photometric data 706 that is initially displayed as part of the light fixture information 702 may be default photometric data associated with the light fixture model 712. After the parameters and/or photometric data associated with the light fixture model 712 and thus with the light fixture 606 are changed, the user may provide an input to the user device 102, for example, by touching a apply user input icon 710 to apply the changes. The user may also provide an input to the user device to move the light fixture model 712, for example, to a location on the site plan image 402.

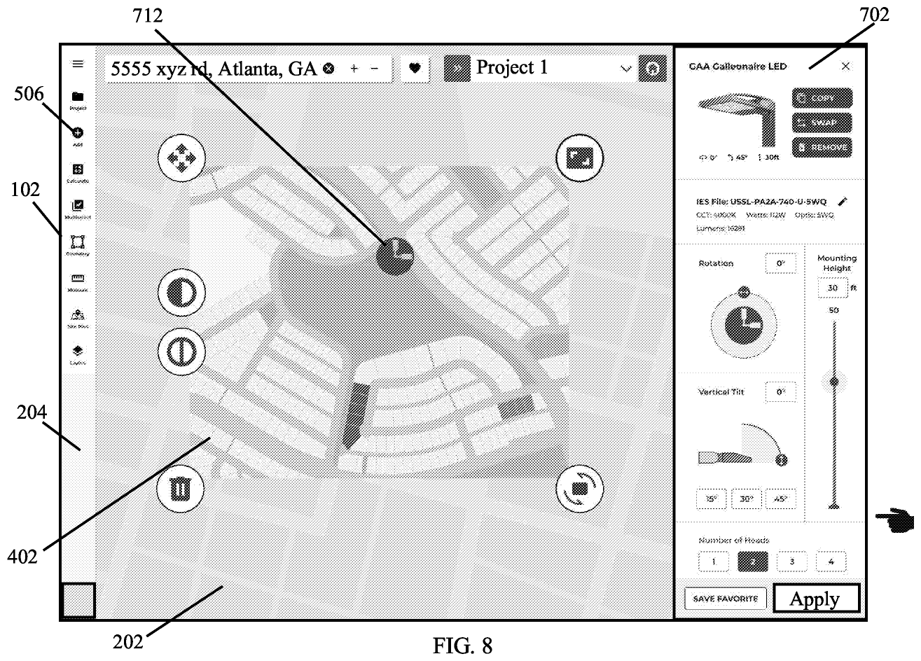

FIG. 8 illustrates the light fixture model 712 of the light fixture 606 of FIG. 6 augmented on the site plan image 402 shown in FIG. 7 according to an example embodiment. Referring to FIGS. 5-8, in some example embodiments, upon the selection of the light fixture 606 from the light fixture menu 602, the user device 102 may initially display the light fixture model 712 on the display screen 204 at a default location. The user may provide an input to the user device to move the light fixture model 712 to another location, such as the location shown in FIG. 8. For example, the user may drag and drop the light fixture model 712 from the location shown in FIG. 7 to the location shown in FIG. 8 such that the light fixture model 712 is augmented on the site plan image 402 that is overlaid on the satellite view image 202. The light fixture information 702 may remain displayed while the light fixture model 712.

In some example embodiments, the user may use the user device 102 to augment more light fixture models of the light fixture 606 or other light fixtures onto the site plan image 402 in the same manner as described with respect to the light fixture model 712. For example, the user may provide a user input to the user device 102 by touching the add light fixture user input icon 506 to augment one or more light fixture models. To illustrate, the user device 102 may display the light fixture menu 602 shown in FIG. 6 in response to the user providing the user input by touching or clicking on the add light fixture user input icon 506. When the light fixture menu 602 is displayed, the user may provide an input to the user device 102 as described above to select a light fixture from the light fixture menu 602. In response to the selection of a light fixture, the user device 102 may display a corresponding light fixture model on the display screen 204 overlaid on the site plan image 402 and/or on the satellite view image 202.

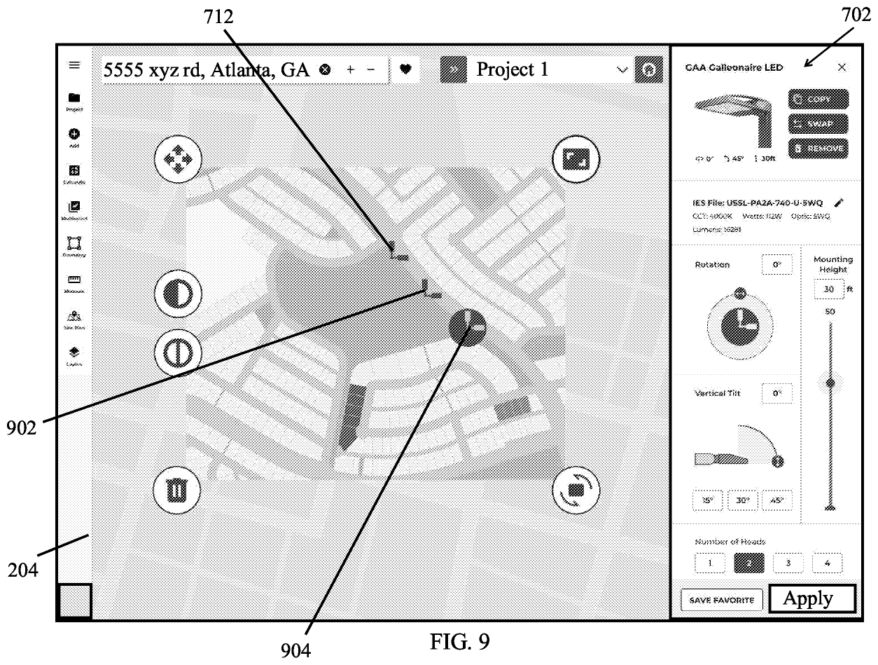

FIG. 9 illustrates multiple light fixture models 712, 902, 904 augmented on the site plan image 402 shown in FIG. 7 according to an example embodiment. Each one of the light fixture models 902, 904 may have been moved to desired locations on the site plan image 402 in the same manner as described above with respect the site plan image 712. In FIG. 9, the light fixture information 702 may correspond to the light fixture model 904 that has been selected by the user. Adjustable parameters and photometric data associated with the light fixture model 904 and the corresponding light fixture may be changed using update options in the light fixture information 702 displayed on the display screen 204. Adjustable parameters and photometric data associated with the light fixture models 712, 902 may be changed in the same manner as described above with respect to the light fixture model 712 by selecting each one of the light fixture models 712, 902.

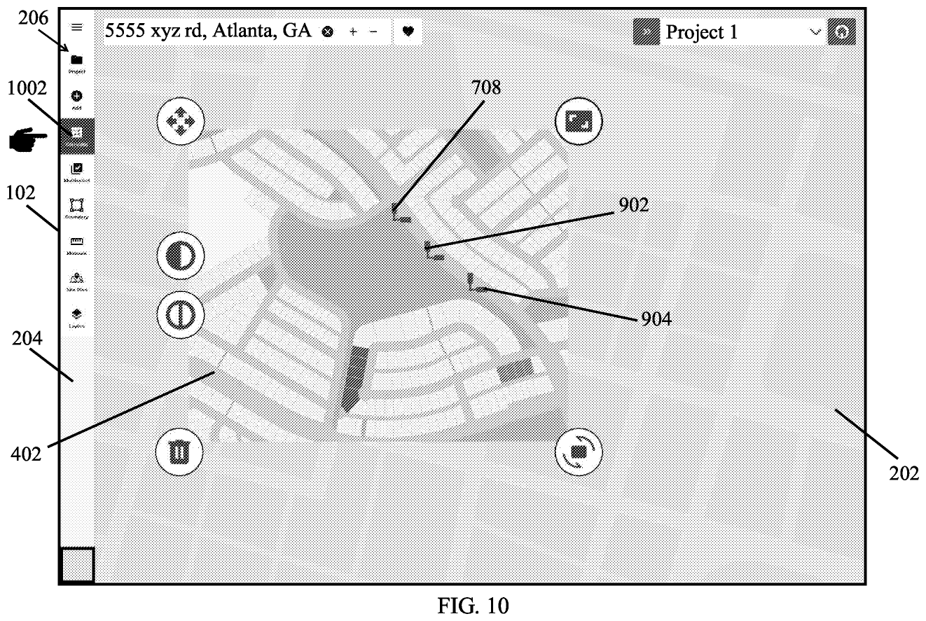

FIG. 10 illustrates the light fixture models 712, 902, 904 augmented on the site plan image 402 shown in FIG. 7 according to an example embodiment. For example, the light fixture models 712, 902, 904 may correspond to the same type of light fixture or to different types of light fixtures. In contrast to FIG. 9, in FIG. 10, the light fixture information 702 shown in FIG. 9 is not displayed, for example, because none of the light fixture models 712, 902, 904 has been selected. For example, the adjustable parameters and/or photometric data associated with the light fixture models 712, 902, 904 may have already been updated or no updates may have been performed.

In some example embodiments, the user may provide a user input to the user device 102 by touching or clicking on the calculate user input icon 1002. In response to the user input, the user device 102 may generate or otherwise determine illuminance information based on the photometric data and parameters associated with the light fixture models 712, 902, 904 and corresponding light fixtures. For example, using photometric data associated with the light fixture models 712, 902, 904, the user device may calculate or otherwise determine illuminance values (e.g., foot-candle values) at various locations relative to the locations of the light fixture models 712, 902, 904 based on one or more of mounting heights, light fixture orientation, vertical tilt, number of heads, etc. as can be readily understood by those of ordinary skill in the art with the benefit of this disclosure. The satellite view image 202 provided by the server 104 shown in FIG. 1 may include actual (i.e., real life) location information that enables the user device 102 to determine the actual distance between two locations in the satellite view image 202 and the site plan image 402.

In some alternative embodiments, illuminance information may be generated after the light fixture model 712 is augmented on the site plan image 402 and before light fixture models 902, 904 are added as shown in FIG. 9. For example, the illuminance information may be generated based on parameters and other information associated with the light fixture model 712 and subsequently regenerated or otherwise updated after one or more of other light fixture models such as the light fixture models 902, 904 are augmented on the site plan image 402.

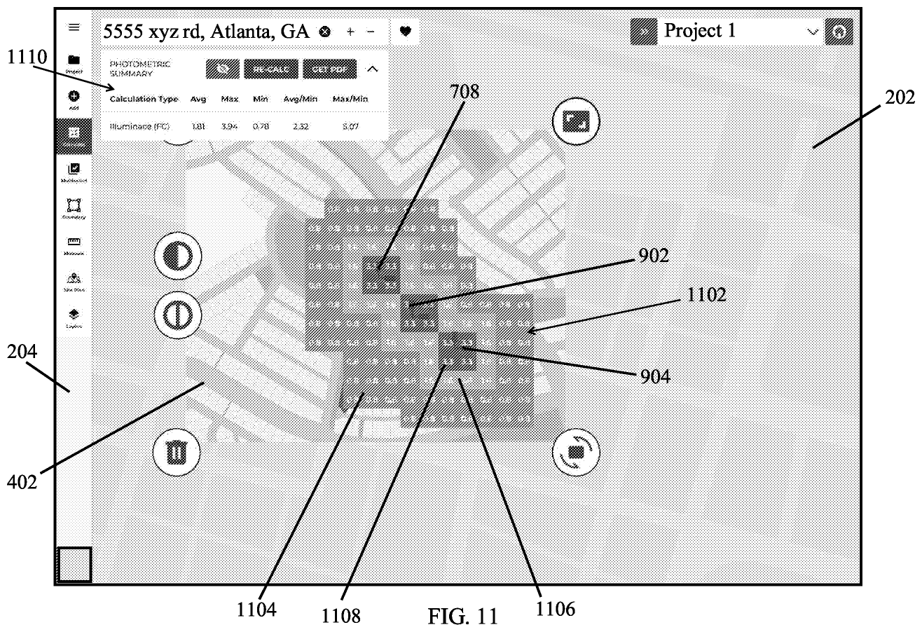

FIG. 11 illustrates illuminance information 1102 overlaid on the site plan image 402 according to an example embodiment. In some example embodiments, the illuminance information 1102 may include a heat map and/or illuminance values. The heat map may represent different illuminance values (e.g., footcandle values) or ranges of illuminance values in respective colors or shades of the same color. The color or shade of the heat map at a particular location on the site plan image 402 may indicate the illuminance at the particular location or the range of illuminance at in an area (e.g., X feet by Y feet area) that includes the particular location. For example, a high range of highest illuminance values may be represented by red or a shade of gray, a low range of lowest illuminance values may be represented in blue or another shade of gray, and a middle range of illuminance values between the two ranges may be represented in green or yet another shade of gray. For example, a heat map section 1104 shown in FIG. 11 may correspond to the low range, a heat map section 1106 may correspond to the middle range, and a heat map section 1108 may correspond to the high range.

In some example embodiments, an illuminance value overlaid at a location on the site plan image 402 may indicate the illuminance at that particular location or an average illuminance for an area that includes the particular location. In general, illuminance values below a certain threshold may not be displayed and/or represented by the heat map 1102 on the display screen 204.

In some example embodiments, the user device 102 may generate and display a photometric summary 1110. For example, the photometric summary 1110 may include information such as average illuminance value, maximum and minimum illuminance values, etc. The user device 102 may also provide the user an option to generate output files of the photometric summary 1110. In some example embodiments, the user device 102 may generate a bill of material in or along with the photometric summary 1110.

By using overlaying a site plan image (e.g., a construction site plan) on an existing satellite view image of an area and by augmenting the site plan image with light fixture models, the user device 102 can be used to efficiently perform lighting design for an outdoor. Because locations and distance can be determined from satellite view images, the use of a satellite view image along with the light fixture models and associated configurable parameters enable lighting design operations to be efficiently performed without a physical presence at the outdoor location. Referring to FIGS. 1-11, in general, a user may provide inputs to the user device using other means instead of or in addition to typing and clicking or touching user input icons displayed on the display screen 204 of the user device 102 as can be readily understood by those of ordinary skill in the art with the benefit of this disclosure. In some alternative embodiments, user input fields, pop-up windows, and the user input icons (e.g., the rotate user input icon 406) may be at different locations than shown without departing from the scope of this disclosure. In some alternative embodiments, the rotation guide 502 shown in FIG. 5 may be omitted and the user device 102 may rotate the site plan image 402 to a desired orientation relative to the satellite view image 202 based by other means such as by moving a finger while touching the site plan image 402 with the finger. In general, the light fixture menu 602 may have a different format than shown in FIG. 6 without departing from the scope of this disclosure. In some alternative embodiments, the light fixture menu 602 may include multiple pages and may include more or fewer light fixtures from which a user can select a particular light fixture. In some alternative embodiments, the display screen 204 may be a physically separate device from the user device 102 without departing from the scope of this disclosure.

In some alternative embodiments, more or fewer light fixture models may be augmented on the site plan image 402 shown in FIG. 10 without departing from the scope of this disclosure. In some example embodiments, the light fixture information 702 shown in FIGS. 7-9 may include more or less information than shown without departing from the scope of this disclosure. For example, more or fewer parameters may be included in the light fixture information 702 for modification by the user. In some alternative embodiments, one or more of the light fixture models 712, 902, 904 shown in FIG. 10 may be at different locations on the site plan image 402 without departing from the scope of this disclosure. In some alternative embodiments, the illuminance information 1102 may also be displayed on one or more areas of the satellite view image 202 that are not overlaid by the site plan image 402 without departing from the scope of this disclosure.

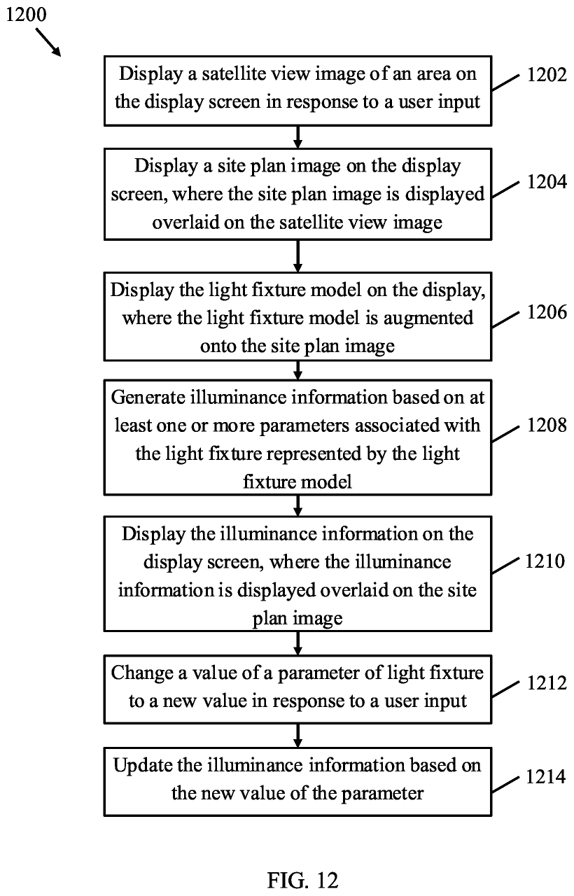

FIG. 12 illustrates an outdoor lighting design method 1200 according to an example embodiment. Referring to FIGS. 1-12, in some example embodiments, at step 1202, the method 1200 includes displaying, by the user device 102, the satellite view image 202 of an area on the display screen 204 in response to a user input. At step 1204, the method 1200 may include displaying, by the user device 102, the site plan image 402 on the display screen 204, where the site plan image 402 is displayed overlaid on the satellite view image 202 that is displayed on the display screen 204. At step 1206, the method 1200 may include displaying, by the user device 102, the light fixture model 712 on the display screen 204 as shown in FIG. 8, where the light fixture model 712 is augmented onto the site plan image 402 displayed on the display screen 204. At step 1208, the method 1200 may include generating, by the user device 102, illuminance information 1102 shown in FIG. 11 based on at least one or more parameters of the light fixture 606 represented by the light fixture model 712. At step 1210, the method 1200 may include displaying, by the user device 102, the illuminance information 1102 on the display screen 204, where the illuminance information 1102 is displayed overlaid on the site plan image 402.

In some example embodiments, the method 1200 may include displaying the light fixture menu 602. As described above, the light fixture model 712 is displayed on the display screen 204 in response to a selection of the light fixture 606 from the light fixture menu 602. The method 1200 may also include displaying, by the user device 102, the illuminance information 1102 on the display screen 204, where the illuminance information 1102 is displayed overlaid on the site plan image 402. The method 1200 may also include, at step 1212, changing a value of a parameter of the one or more parameters of light fixture to a new value in response to a user input. At step 1214, the method 1200 may include updating the illuminance information that was determined by the user device 102 based on the new value of the parameter.

In some example embodiments, the method 1200 may include moving or rotating the site plan image 402 relative to the satellite view image 202 in response to a user input after the site plan image 402 is displayed overlaid on the satellite view image 202. The method 1200 may also include resizing the site plan image 402 in response to a user input after the site plan image 402 is displayed overlaid on the satellite view image 202. The method 1200 may also include moving the light fixture model 712 displayed on the display screen 204 to a new location on the site plan image 402 displayed on the display screen 204. The method 1200 may also include displaying, by the user device 102, a second light fixture model 902 on the display screen 204, where the second light fixture model 902 is displayed augmented onto the site plan image 402 displayed on the display screen 204 as shown in FIG. 9. The method 1200 may also include generating the illuminance information further based on photometric data associated with the light fixture model 712 and photometric data associated with the light fixture model 902.

In some alternative embodiments, one or more steps of the method 1200 may be omitted without departing from the scope of this disclosure. In some alternative embodiments, one or more steps of the method 1200 may be performed in a different order than described above without departing from the scope of this disclosure. In some alternative embodiments, the method 1200 may include steps than other than those described above without departing from the scope of this disclosure.

Although particular embodiments have been described herein in detail, the descriptions are by way of example. The features of the example embodiments described herein are representative and, in alternative embodiments, certain features, elements, and/or steps may be added or omitted. Additionally, modifications to aspects of the example embodiments described herein may be made by those skilled in the art without departing from the spirit and scope of the following claims, the scope of which are to be accorded the broadest interpretation so as to encompass modifications and equivalent structures.

What is claimed is:

1. A method of lighting design for outdoor areas based on light fixture model augmentation, the method comprising:
displaying, by a user device, a satellite view image of an area on a display screen;
displaying, by the user device, a site plan image on the display screen, wherein the site plan image is displayed overlaid on the satellite view image that is displayed on the display screen;
displaying, by the user device, a light fixture model on the display screen, wherein the light fixture model is augmented onto the site plan image displayed on the display screen;
generating, by the user device, illuminance information based on at least one or more parameters associated with a light fixture represented by the light fixture model; and
displaying, by the user device, the illuminance information on the display screen, wherein the illuminance information is displayed overlaid on the site plan image.

2. The method of claim 1, further comprising displaying a light fixture menu, wherein the light fixture model is displayed on the display screen in response to a selection of the light fixture from the light fixture menu.

3. The method of claim 1, further comprising changing a value of a parameter of the one or more parameters associated with the light fixture to a new value in response to a user input, wherein the illuminance information is updated based on the new value of the parameter.

4. The method of claim 3, wherein the parameter of the light fixture is an orientation of the light fixture, an installation height of the light fixture, a number of heads of the light fixture, or a vertical tilt angle of the light fixture.

5. The method of claim 1, wherein the illuminance information is generated further based on at least photometric data associated with the light fixture model.

6. The method of claim 1, further comprising moving or rotating the site plan image relative to the satellite view image in response to a user input after the site plan image is displayed overlaid on the satellite view image.

7. The method of claim 1, further comprising resizing the site plan image in response to a user input after the site plan image is displayed overlaid on the satellite view image.

8. The method of claim 1, further comprising moving the light fixture model displayed on the display screen to a new location on the site plan image displayed on the display screen.

9. The method of claim 1, further comprising displaying, by the user device, a second light fixture model on the display screen, wherein the second light fixture model is displayed augmented onto the site plan image displayed on the display screen.

10. The method of claim 1, further comprising automatically performing one or more of moving, rotating, and resizing the site plan image displayed on the display screen based on structural features in the satellite view image.

11. The method of claim 1, wherein the site plan image is a construction site plan image.

12. A device for performing a lighting design for outdoor areas based on light fixture model augmentation, the device comprising:
a user interface configured to receive user inputs;
a display screen; and
a processor configured to:
display a satellite view image of an area on the display screen;
display a site plan image on the display screen in response to a user input received via the user interface, wherein the site plan image is displayed overlaid on the satellite view image displayed on the display screen;
display a light fixture model on the display screen, wherein the light fixture model is augmented onto the site plan image displayed on the display screen;
generate illuminance information based on at least one or more parameters associated with a light fixture represented by the light fixture model; and
display the illuminance information on the display screen, wherein the illuminance information is displayed overlaid on the site plan image.

13. The device of claim 12, wherein the processor is further configured to change a value of a parameter associated with the light fixture to a new value in response to a second user input and to update the illuminance information based on the new value of the parameter.

14. The device of claim 12, wherein the processor is further configured to move or rotate the site plan image relative to the satellite view image in response to a second user input after the site plan image is displayed overlaid on the satellite view image.

15. The device of claim 12, wherein the processor is further configured to display a second light fixture model on the display screen in response to a second user input, wherein the second light fixture model is displayed augmented onto the site plan image, and wherein the illuminance information is generated further based on first photometric data associated with the light fixture model and second photometric data associated with the second light fixture model.
